(19) United States
(12) Patent Application Publication
(10) Pub. No.: US 2020/0243588 A1
(43) Pub. Date: Jul. 30, 2020

(54) PACKAGING STRUCTURE AND PACKAGING METHOD

(71) Applicant: China Wafer Level CSP Co., Ltd., People's Republic of China (CN)

(72) Inventors: Zhiqi Wang, Suzhou, Jiangsu (CN); Zhuowei Wang, Suzhou, Jiangsu (CN); Lijun Chen, Suzhou, Jiangsu (CN)

(73) Assignee: China Wafer Level CSP Co., Ltd., People's Republic of China (CN)

(21) Appl. No.: 16/305,365

(22) PCT Filed: May 25, 2017
(86) PCT No.: PCT/CN2017/085915

§ 371 Date: Nov. 28, 2018

(51) Int. Cl. H01L 27/146

(52) U.S. Cl. CPC H01L 27/14618; H01L 27/14685; H01L 27/14687; H01L 27/14623; H01L 27/14632

(57) ABSTRACT

A package and a packaging method are provided. The package includes a chip unit, a protective cover plate, and an adhesive unit. The chip unit has a first surface, where the first surface includes a device region. The protective cover plate has a second surface opposite to the first surface of the chip unit. The adhesive unit is located between the first surface of the chip unit and the second surface of the protective cover plate and is configured to bond the chip unit with the protective cover plate. The adhesive unit includes a first region and a second region having different viscosities.

The present application claims priorities to Chinese Patent Application No. 201610369670.X, titled “PACKAGING STRUCTURE AND PACKAGING METHOD”, filed with the Chinese Patent Office on May 30, 2016, and Chinese Patent Application No. 201620506547.3, titled “PACKAGING STRUCTURE”, filed with the Chinese Patent Office on May 30, 2016, both of which are incorporated herein by reference in their entireties.

### FIELD

The present disclosure relates to the technical field of semiconductor packaging, and in particular to a package and a packaging method.

### BACKGROUND

The Wafer Level Chip Size Packaging (WLCSP) technology is a technology in which a full wafer is packaged and tested, and then is cut to acquire individual finished chips. The packaged chip formed by using the Wafer Level Chip Size Packaging technology has a quite small size, so that the cost of the chip is greatly reduced with the reduction in the size of the chip and the increase in the size of the wafer, which meets the market requirement for lighter, smaller, shorter, thinner and cheaper microelectronic products. The technology is a hotspot in the current packaging field, and represents a development trend in the future.

An image sensing chip that converts an optical image signal into an electronic signal, has a sensing region. In the process that the image sensing chip is packaged by using the existing Wafer Level Chip Size Packaging technology, a package cover is generally formed in the sensing region to protect the sensing region of the image sensor from damage or contamination. The package cover is usually a transparent substrate to ensure normal transmission of light. The transparent substrate may serve as a support during the process of forming the image sensing chip package, so that the packaging process can be performed smoothly. After the wafer level chip packaging process, the transparent substrate is still retained to protect the sensing region from damage or contamination during use of the image sensing chip.

However, due to the presence of the transparent substrate, the performance of the image sensing chip may be reduced, which is caused by the fact that the transparent substrate absorbs, refracts, and/or reflects a part of light entering the sensing region of the image sensing chip more or less, affecting the quality of the image sensing. In addition, the transparent substrate having excellent optical performance is usually expensive.

In the conventional technology, the transparent substrate is usually removed after the wafer level chip packaging process. However, the sensing region of the image sensing chip without the transparent substrate may be subjected to damage or contamination in a subsequent process that the package is installed on a board at the client (for example, in a process that the package is electrically connected with a printed circuit board).

Therefore, it is desired to provide a packaging method by which the sensing region of the image sensing chip can be protected from damage and contamination without affecting the performance.

### SUMMARY

An object of the present disclosure is to provide a package and a packaging method to protect a sensing region of an image sensing chip without affecting performance of an image sensor.

In order to reach the above object, a package and a packing method are provided according to embodiments of the present disclosure. The package includes: a chip unit having a first surface, where the first surface includes a device region; a protective cover plate having a second surface opposite to the first surface of the chip unit; and an adhesive unit located between the first surface of the chip unit and the second surface of the protective cover plate and configured to bond the chip unit with the protective cover plate, where the adhesive unit includes a first region and a second region having different viscosities.

Optionally, the viscosity of the first region is less than the viscosity of the second region.

Optionally, the viscosity of the first region is zero.

Optionally, the first region accounts for 30% to 90% by volume of the adhesive unit.

Optionally, the adhesive unit includes a first adhesive layer, with the first region and the second region being in the first adhesive layer.

Optionally, the adhesive unit includes a first adhesive layer, a second adhesive layer and a transparent base located between the first adhesive layer and the second adhesive layer. The first adhesive layer is located between the transparent base and the second surface of the protective cover plate, and the second adhesive layer is located between the transparent base and the first surface of the chip unit.

Optionally, the first region and the second region are located in the first adhesive layer.

Optionally, the first region of the adhesive unit is the first adhesive layer, and the second region of the adhesive unit is the second adhesive layer.

Optionally, the package further includes a support structure located between the first surface of the chip unit and the adhesive layer, with the device region being located in a groove surrounded by the support structure and the adhesive layer.

Optionally, the package further includes a support structure located between the first surface of the chip unit and the adhesive layer, where the support structure is bonded with the first surface of the chip unit by an adhesive layer, with the device region being located in a groove surrounded by the support structure and the adhesive layer.

A packaging method is further provided according to an embodiment of the present disclosure, which includes: providing a chip unit having a first surface, where the first surface includes a device region; providing a protective cover plate having a second surface; and forming an adhesive unit for bonding the first surface of the chip unit with the second surface of the protective cover plate, where the adhesive unit includes a first region and a second region having different viscosities.

Optionally, the forming an adhesive unit for bonding the first surface of the chip unit with the second surface of the protective cover plate includes: forming an adhesive unit having a variable viscosity and bonding the first surface of the chip unit with the second surface of the protective cover plate; and processing the adhesive unit to form the first region and the second region having different viscosities in the adhesive unit.

Optionally, the viscosity of the first region is less than the viscosity of the second region.

Optionally, the viscosity of the first region is zero.

Optionally, the first region accounts for 30% to 90% by volume of the adhesive unit.

Optionally, the adhesive unit includes a first adhesive layer.

Optionally, the adhesive unit includes a first adhesive layer, a second adhesive layer and a transparent base located between the first adhesive layer and the second adhesive layer, where the first adhesive layer is located between the transparent base and the second surface of the protective cover plate, and the second adhesive layer is located between the transparent base and the first surface of the chip unit.

Optionally, the processing the adhesive unit to form the first region and the second region having different viscosities in the adhesive unit includes: processing the first adhesive layer to form the first region and the second region in the first adhesive layer.

Optionally, the processing the adhesive unit to form the first region and the second region having different viscosities in the adhesive unit includes: processing the first adhesive layer to decrease a viscosity of the first adhesive layer, where the first adhesive layer serves as the first region of the adhesive unit, and the second adhesive layer serves as the second region of the adhesive unit.

Optionally, the first adhesive layer is made of a photosensitive adhesive having a first debonding wavelength, and processing the first adhesive layer to form the first region and the second region having different viscosities in the first adhesive layer includes: irradiating a portion of the first adhesive layer with a light source having the first debonding wavelength, where a viscosity of the portion of the first adhesive layer irradiated by the light source is decreased to form the first region, and a viscosity of a portion of the first adhesive layer not irradiated by the light source is not changed to form the second region.

Optionally, the first adhesive layer is made of a photosensitive adhesive having a first debonding wavelength, the second adhesive layer is made of a photosensitive adhesive having a second debonding wavelength not equal to the first debonding wavelength, and the processing the adhesive unit to form the first region and the second region having different viscosities in the adhesive unit includes: irradiating the adhesive unit with a light source having the first debonding wavelength, where the viscosity of the first adhesive layer is decreased to be zero to form the first region, and a viscosity of the second adhesive layer is not changed to form the second region.

Optionally, the light source is a laser light source, and the irradiating a portion of the first adhesive layer includes: irradiating a portion of a third surface of the protective cover plate with the laser light source along a predetermined path, where the third surface is opposite to the second surface.

Optionally, the light source is a surface light source, and the irradiating a portion of the first adhesive layer includes: forming a patterned light shielding layer on a third surface of the protective cover plate, with the patterned light shielding layer exposing a portion of the protective cover plate, where the third surface is opposite to the second surface; and irradiating the third surface with the surface light source.

Optionally, the protective cover plate is made of a light transmissive material.

Optionally, the first adhesive layer is made of a hot melt adhesive, and processing the first adhesive layer to form the first region and the second region having different viscosities in the first adhesive layer includes: irradiating a portion of the first adhesive layer by using laser or ultrasound, where a viscosity of the portion irradiated is decreased to form the first region, and a viscosity of a portion of the first adhesive layer not irradiated is not changed to form the second region.

Optionally, the forming an adhesive unit having a variable viscosity and bonding the first surface of the chip unit with the second surface of the protective cover plate includes: forming an adhesive unit on the second surface of the protective cover plate and bonding the first surface of the chip unit with the adhesive unit; or forming an adhesive unit on the first surface of the chip unit and bonding the second surface of the protective cover plate with the adhesive unit.

Optionally, the forming an adhesive unit having a variable viscosity and bonding the first surface of the chip unit with the second surface of the protective cover plate includes: forming an adhesive unit on the second surface of the protective cover plate and bonding the first surface of the chip unit with the adhesive unit; or forming an adhesive unit on the first surface of the chip unit and bonding the second surface of the protective cover plate with the adhesive unit.

Optionally, the forming an adhesive unit having a variable viscosity and bonding the first surface of the chip unit with the second surface of the protective cover plate includes: forming an adhesive unit on the protective cover plate; forming a support structure on the adhesive unit; and bonding the support structure with the first surface of the chip unit by an adhesive layer, with the device region being located in a groove surrounded by the support structure and a surface of the adhesive unit.

Optionally, the chip unit is on a to-be-packaged wafer including multiple chip units and a cutting trench formed between adjacent chip units among the multiple chip units. The chip unit further includes contact pads located on the first surface and outside the device region. After bonding the first surface of the chip unit with the adhesive layer and before processing the adhesive layer, the package method further includes: thinning the to-be-packaged wafer on a fourth surface of the to-be-packaged wafer, where the fourth surface of the to-be-packaged wafer is opposite to the first surface; etching the to-be-packaged wafer on the fourth surface of the to-be-packaged wafer to form through holes, where each of the through holes exposes one of the contact pads; forming an insulation layer on the fourth surface of the to-be-packaged wafer and sidewalls of the through holes; forming a metal layer connected with the contact pads on the insulation layer; forming a solder mask on the metal layer and the insulation layer, where the solder mask is provided with openings to expose a portion of the metal layer; forming solder bumps on the solder mask, where each of the solder bumps fills one of the openings; and cutting the to-be-packaged wafer, the adhesive layer and the protective cover plate along the cutting trench to form multiple separate packages.

With the package according to the embodiment of the present disclosure, since the adhesive unit has the first region and the second region having different viscosities, where the viscosity of the first region is less than the viscosity of the second region, so that the bonding force between the chip unit and the protective cover plate can be reduced but not completely eliminated. In a subsequent process that the package is installed on a board at the client, the protective cover plate can still protect the package from contamination or damage. After the package is installed on the board at the client, the protective cover plate can be easily removed, which prevents the protective cover plate from adversely affecting performance of the chip unit during use of the chip unit.

Further, the adhesive unit further includes a first adhesive layer, a second adhesive layer and a transparent base located between the first adhesive layer and the second adhesive layer. The first adhesive layer is located between the transparent base and the second surface of the protective cover plate, and the second adhesive layer is located between the transparent base and the first surface of the chip unit. The first adhesive layer serves as the first region, and the second adhesive layer serves as the second region. The protective cover plate is removed before shipment of the package. In a subsequent process that the package is installed on a board at the client, the transparent base can still protect the package from contamination or damage. After the package is installed on the board at the client, the second adhesive layer is irradiated by a light source having the second debonding wavelength to decrease the viscosity of the second adhesive layer, so as to separate the transparent base from the chip unit, which prevents the transparent base from adversely affecting the image quality of the chip unit during use of the chip unit.

With the packaging method according to the embodiment of the present disclosure, an adhesive unit having a variable viscosity is formed between the chip unit and the protective cover plate, and a viscosity of a portion of the adhesive unit is decreased by light irradiation or heating to form a first region and a second region having different viscosities, so that the bonding force between the chip unit and the protective cover plate can be reduced but not completely eliminated. In a subsequent process that the package is installed on a board at the client, the protective cover plate can still protect the package from contamination or damage. After the package is installed on the board at the client, the protective cover plate can be easily removed, which prevents the protective cover plate from adversely affecting performance of the chip unit during use of the chip unit.

Further, the packaging method further includes forming an adhesive unit having a variable viscosity, where the adhesive unit includes a first adhesive layer, a second adhesive layer and a transparent base located between the first adhesive layer and the second adhesive layer. The first adhesive layer is located between the transparent base and the second surface of the protective cover plate, and the second adhesive layer is located between the transparent base and the first surface of the chip unit. The first adhesive layer serves as the first region, and the second adhesive layer serves as the second region. The protective cover plate is removed before shipment of the package. In a subsequent process that the package is installed on a board at the client, the transparent base can still protect the package from contamination or damage. After the package is installed on the board at the client, the second adhesive layer is irradiated by a light source having the second debonding wavelength to decrease the viscosity of the second adhesive layer, so as to separate the transparent base from the chip unit, which prevents the transparent base from adversely affecting the image quality of the chip unit during use of the chip unit.

### BRIEF DESCRIPTION OF THE DRAWINGS

In order to more clearly illustrate technical solutions in the present disclosure and the conventional technology, the drawings to be used in the description of the technical solutions of the present disclosure and the conventional technology are briefly described below. Apparently, the drawings show only some embodiments of the present disclosure, and other drawings may be obtained by those skilled in the art without any creative work.

FIG. 1 is a schematic sectional view of a package according to an embodiment of the present disclosure;

FIG. 2 is a schematic sectional view of a package according to another embodiment of the present disclosure;

FIG. 3 is a schematic sectional view of a package according to another embodiment of the present disclosure;

FIG. 4 is a schematic sectional view of a package according to another embodiment of the present disclosure;

FIG. 5 is a schematic sectional view of a package according to another embodiment of the present disclosure;

FIG. 6 is a schematic top view of a to-be-packaged wafer according to an embodiment of the present disclosure;

FIGS. 7 to 15 are respectively schematic sectional views of intermediate structures formed in a packaging method according to an embodiment of the present disclosure;

FIGS. 16 to 20 are respectively schematic sectional views of intermediate structures formed in a packaging method according to another embodiment of the present disclosure;

FIGS. 21 to 24 are respectively schematic sectional views of intermediate structures formed in a packaging method according to another embodiment of the present disclosure;

FIGS. 25 to 27 are respectively schematic sectional views of intermediate structures formed in a packaging method according to another embodiment of the present disclosure; and

FIGS. 28 to 30 are respectively schematic sectional views of intermediate structures formed in a packaging method according to another embodiment of the present disclosure.

### DETAILED DESCRIPTION OF EMBODIMENTS

A package and a packaging method are provided according to embodiments of the present disclosure, which are described in detail below with reference to the drawings.

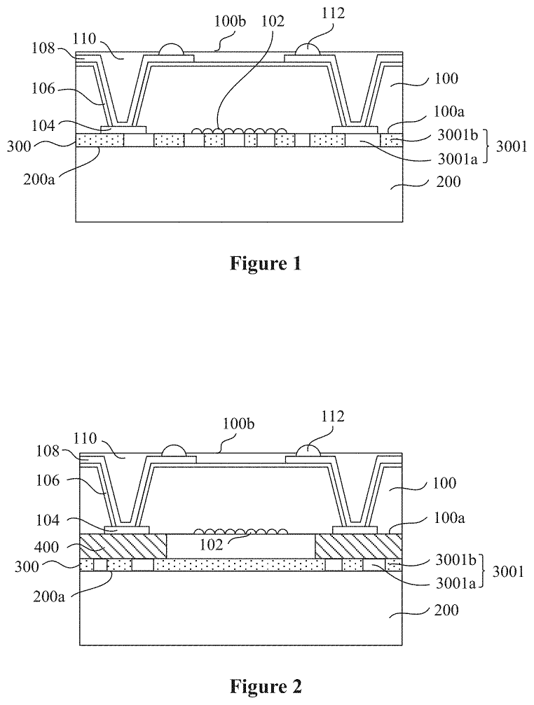

Firstly, a package is provided according to an embodiment of the present disclosure. FIG. 1 is a schematic sectional view of a package according to an embodiment of the present disclosure.

Referring to FIG. 1, the package includes a chip unit 100, a protective cover plate 200, and an adhesive unit. The chip unit 100 has a first surface 100a, and a fourth surface 100b opposite to the first surface 100a. The chip unit 100 includes a device region 102 located on the first surface 100a. The protective cover plate 200 has a second surface 200a opposite to the first surface 100a of the chip unit 100. The adhesive unit is located between the first surface 100a of the chip unit 100 and the second surface 200a of the protective cover plate 200 and is configured to bond the chip unit 100 with the protective cover plate 200. The adhesive unit 300 has a single-layer structure and is implemented by a first adhesive layer 3001. The first adhesive layer 3001 includes a first region 3001a and a second region 3001b having different viscosities.

Specifically, in an embodiment, the chip unit 100 is an image sensing chip unit. The chip unit 100 includes the device region 102 and contact pads 104 located on the first surface 100a. Each of the contact pads 104 is located outside the device region 102 and is used as an input and output terminal for connecting a device in the device region 102 with an external circuit. The chip unit 100 further includes through holes (which are not shown) penetrating through the chip unit 100 from the fourth surface 100b of the chip unit 100. Each of the through holes exposes one of the contact pads 104. The chip unit 100 further includes an insulation layer 106 covering the fourth surface 100b of the chip unit 100 and sidewalls of the through holes. The chip unit 100 further includes: a metal layer 108, a solder mask 110, and solder bumps 112. The metal layer 108 is located on the insulation layer 106 and is electrically connected with the contact pads 104. The solder mask 110 is located on the metal layer 108 and the insulation layer 106, and is provided with openings (which are not shown) to expose a portion of the metal layer 108. Each of the solder bumps 112 fills one of the openings and is exposed outside the solder mask 110. With the above structure, the device region 102 can be connected with the external circuit via the contact pad 104, the metal layer 108, and the solder bump 112 to transmit electrical signals.

The device region 102 is a photosensitive region. For example, the device region 102 may be formed by multiple photodiodes arranged in an array. With the photodiodes, an optical signal irradiated to the device region 102 can be converted into an electrical signal and then transmitted to the external circuit via the contact pad 104. In other embodiments, the device region 102 may be implemented by a physical sensor such as another type of optoelectronic device, a radio frequency device, a surface acoustic wave device, a pressure sensing device, for performing measurement based on a change in a physical quantity such as heat, light, and pressure, or a micro-electromechanical system, or a microfluidic system.

In some embodiments, the protective cover plate 200 is made of a light transmissive material, for example, inorganic glass or organic glass.

The first adhesive layer 3001 is made of an adhesive having a variable viscosity, for example, a photosensitive adhesive or a hot melt adhesive. The viscosity of the first region 3001a is less than the viscosity of the second region 3001b.

In some embodiments, the first adhesive layer 3001 is made of an ultraviolet photosensitive adhesive, and the viscosity of the ultraviolet photosensitive adhesive in the first region 3001a is less than that in the second region 3001b. With the first region 3001a and the second region 3001b having different viscosities, the bonding force between the chip unit 100 and the protective cover plate 200 can be reduced but not completely eliminated as compared with the case that the adhesive layer has a uniform and full viscosity. In an embodiment, the viscosity of the first region 3001a is zero.

In some embodiments, the first region 3001a accounts for 30% to 90% by volume of the first adhesive layer 3001. For example, the first region 3001a may account for 50%, 60%, 70% or 80% by volume of the first adhesive layer 3001. In this case, the bonding force between the chip unit 100 and the protective cover plate 200 can be reduced but not completely eliminated.

It should be noted that the first adhesive layer 3001 is made of the ultraviolet photosensitive adhesive. This is because that the viscosity of the ultraviolet photosensitive adhesive can significantly change before being irradiated by the ultraviolet light and after being irradiated by the ultraviolet light. Thus, the viscosity of the ultraviolet photosensitive adhesive can be controlled by controlling external impacts such as a time period and power of the ultraviolet light radiation, so as to form the first region 3001a and the second region 3001b having different viscosities.

In other embodiments, the first adhesive layer 3001 is made of a hot melt adhesive. The first region 3001a and the second region 3001b having different viscosities may be formed by positioning a portion of the first adhesive layer 3001 by using laser or ultrasound and heating the portion of the first adhesive layer 3001.

It should be noted that, in the embodiment of the present disclosure, the first adhesive layer 3001 having a variable viscosity is illustrated by taking a photosensitive adhesive or a hot melt adhesive as an example. Practically, the first adhesive layer 3001 having a variable viscosity may be made of other materials, which is not limited thereto, as long as the viscosity of the first adhesive layer 3001 can significantly change with external conditions to form the first region and the second region having different viscosities. All of solutions meeting the above condition obey the spirit of the present disclosure and fall in the protection scope of the present disclosure.

In a subsequent process that the package is installed on a board at the client, for example, in a process that the package is electrically connected with a circuit board such as a Printed Circuit Board (PCB), the protective cover plate 200 can still protect the package from contamination or damage. After the package is installed on the board at the client, the protective cover plate 200 can be easily removed due to the weak bonding force between the chip unit 100 and the protective cover plate 200. For example, the protective cover plate 200 may be separated from the chip unit 100 by applying an adsorption force to the back of the protective cover plate 200 by vacuum adsorption or electrostatic adsorption. Further, the first surface 100a of the chip unit 100 may be cleaned to remove the adhesive layer remaining on a surface of a photosensitive region.

After the package is installed on the board, the protective cover plate 200 is removed, which prevents the protective cover plate 200 from adversely affecting the image quality of the chip unit 100 during use of the chip unit 100, which is caused by the fact that the protective cover plate 200 absorbs, refracts and/or reflects light and thus affects an amount of light entering into the device region 102.

FIG. 2 is a schematic sectional view of a package according to another embodiment of the present disclosure.

Referring to FIG. 2, this embodiment differs from the previous embodiment in that the package further includes a support structure 400 located between the first surface 100a of the chip unit 100 and the first adhesive layer 3001, and the device region 102 is located in a groove surrounded by the support structure 400 and the first adhesive layer 3001.

In some embodiments, the support structure 400 may be made of a photoresist, resin, silicon oxide, silicon nitride, or silicon oxynitride. The viscosity of the first region 3001a is less than that of the second region 3001b in the first adhesive layer 3001. In an embodiment, the viscosity of the first region 3001a is zero.

It should be noted that, in this embodiment, since only a portion of the first adhesive layer 3001 between the support structure 400 and the second surface 200a is used for adhering, the first region 3001a is only distributed between the support structure 400 and the second surface 200a to reduce the bonding force between the chip unit 100 and the protective cover plate 200, and the second region 3001b is all distributed at a portion of the second surface 200a opposite to the device region 102. In some embodiments, the first region 3001a accounts for 30%, by volume of the first adhesive layer 3001, so that the bonding force between the chip unit 100 and the protective cover plate 200 can be reduced but not completely eliminated.

With the package in this embodiment, the bonding force between the chip unit 100 and the protective cover plate 200 can still be reduced but not completely eliminated. In a subsequent process that the package is installed on a board at the client, the protective cover plate 200 can still protect the package from contamination or damage. After the package is installed on the board at the client, the protective cover plate 200 can be easily removed, which prevents the protective cover plate 200 from adversely affecting the image quality of the chip unit 100.

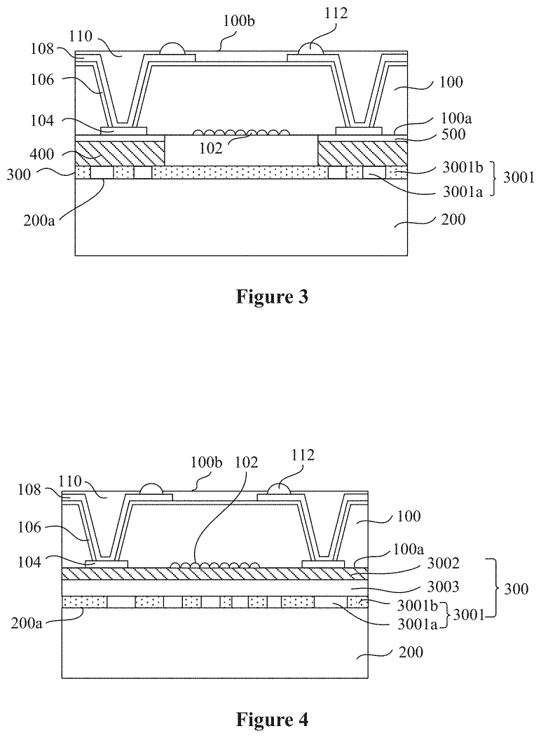

FIG. 3 is a schematic sectional view of a package according to another embodiment of the present disclosure.

Referring to FIG. 3, this embodiment differs from the previous embodiment in that the package further includes an adhesive layer 500, and the support structure 400 is bonded with the first surface 100a of the chip unit 100 by the adhesive layer 500.

The adhesive layer 500 may be made of an adhesive having a constant viscosity or a variable viscosity. In some embodiments, the adhesive layer 500 is made of an adhesive having a constant viscosity, including an encapsulated adhesive such as epoxy resin.

In other embodiments, the adhesive layer 500 may be made of an adhesive having a variable viscosity, which is different from the adhesive forming the first adhesive layer 3001 in property. For example, the first adhesive layer 3001 is made of a photosensitive adhesive, and the adhesive layer 500 is made of a hot melt adhesive. Alternatively, the first adhesive layer 3001 is made of a hot melt adhesive, and the adhesive layer 500 is made of a photosensitive adhesive. That is, in a subsequent process that the viscosity of a portion of the first adhesive layer 3001 is changed by light irradiating or heating to form the first region 3001a and the second region 3001b having different viscosities, the viscosity of the adhesive layer 500 can remain unchanged.

With the package in this embodiment, the bonding force between the chip unit 100 and the protective cover plate 200 can still be reduced but not completely eliminated. In a subsequent process that the package is installed on a board at the client, the protective cover plate 200 can still protect the package from contamination or damage. After the package is installed on the board at the client, the protective cover plate 200 can be easily removed, which prevents the protective cover plate 200 from adversely affecting the image quality of the chip unit 100.

FIG. 4 is a schematic sectional view of a package according to another embodiment of the present disclosure.

Referring to FIG. 4, this embodiment differs from the embodiment shown in FIG. 1 in that the adhesive unit 300 in the package in this embodiment has a multi-layer structure. The adhesive unit 300 includes the first adhesive layer 3001, a second adhesive layer 3002, and a transparent base 3003 located between the first adhesive layer 3001 and the second adhesive layer 3002. The first adhesive layer 3001 is located between the transparent base 3003 and the second surface 200a of the protective cover plate 200. The second adhesive layer 3002 is located between the transparent base 3003 and the first surface 100a of the chip unit 100. The first adhesive layer 3001 includes the first region 3001a and the second region 3001b having different viscosities.

In some embodiments, the first adhesive layer 3001 is made of a photosensitive adhesive having a first debonding wavelength, and the second adhesive layer 3002 is made of a photosensitive adhesive having a second debonding wavelength not equal to the first debonding wavelength. The first region 3001a and the second region 3001b are formed by irradiating a portion of the first adhesive layer 3001 with a light source having the first debonding wavelength. The viscosity of the first region 3001a is less than that of the second region 3001b. In an embodiment, the viscosity of the first region 3001a is zero.

With the package according to this embodiment, the bonding force between the chip unit 100 and the protective cover plate 200 can still be reduced but not completely eliminated. In a subsequent process that the package is installed on a board at the client, the adhesive unit 300 can protect the package from contamination or damage. After the package is installed on the board at the client, the protective cover plate 200 can be easily removed, and then a portion of the second adhesive layer 3002 is irradiated by a light source having the second debonding wavelength to decrease the viscosity of the second adhesive layer 3002, so as to separate the transparent base 3003 from the chip unit 100, which prevents the transparent base 3003 from adversely affecting the image quality of the chip unit 100 during use of the chip unit 100.

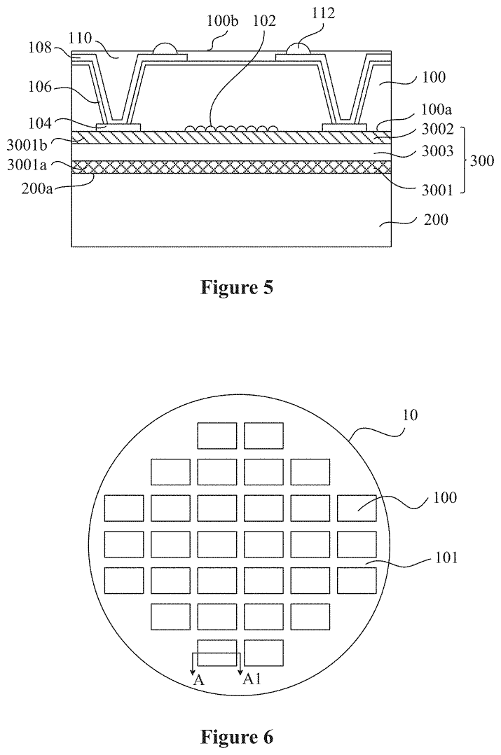

FIG. 5 is a schematic sectional view of a package according to another embodiment of the present disclosure;

Referring to FIG. 5, this embodiment is similar to the previous embodiment. The package in this embodiment includes the chip unit 100, the protective cover plate 200, and the adhesive unit 300. The adhesive unit 300 has a multi-layer structure, including the first adhesive layer 3001, the second adhesive layer 3002, and the transparent base 3003 located between the first adhesive layer 3001 and the second adhesive layer 3002. Structures of the chip unit 100 and the protective cover plate 200 in this embodiment are the same as those in the embodiment shown in FIG. 1, which are not repeated herein.

This embodiment differs from the previous embodiment in that the first region 3001a of the adhesive unit 300 is the first adhesive layer 3001, and the second region 3001b of the adhesive unit 300 is the second adhesive layer 3002. The viscosity of the first adhesive layer 3001 is less than that of the second adhesive layer 3002. In some embodiments, the first region 3001a accounts for 30% by volume of the adhesive unit 300.

In an embodiment, the first adhesive layer 3001 is formed by irradiating a photosensitive adhesive having a first debonding wavelength with a light source having the first debonding wavelength, and the second adhesive layer 3002 is made of a photosensitive adhesive having a second debonding wavelength not equal to the second debonding wavelength. Therefore, the first region 3001a of the adhesive unit 300 has a small viscosity, so that the protective cover plate 200 can be easily separated from the transparent base 3003. With the package according to this embodiment of the present disclosure, the protective cover plate 200 can be removed before shipment of the package, and the package including the chip unit 100, the transparent base 3003 and the second adhesive layer 3002 is provided to the client. In a subsequent process that the package is installed on a board at the client, the transparent base 3003 can still protect the package from contamination or damage. After the package is installed on the board at the client, the second adhesive layer 3002 is irradiated by a light source having the second debonding wavelength to decrease the viscosity of the second adhesive layer 3002, so as to separate the transparent base 3003 from the chip unit 100, which prevents the transparent base 3003 from adversely affecting the image quality of the chip unit 100 during use of the chip unit 100.

Correspondingly, a packaging method for forming the package shown in FIG. 1 is further provided according to an embodiment of the present disclosure.

FIGS. 6 to 15 are respectively schematic sectional views of intermediate structures formed in a packaging method according to an embodiment of the present disclosure.

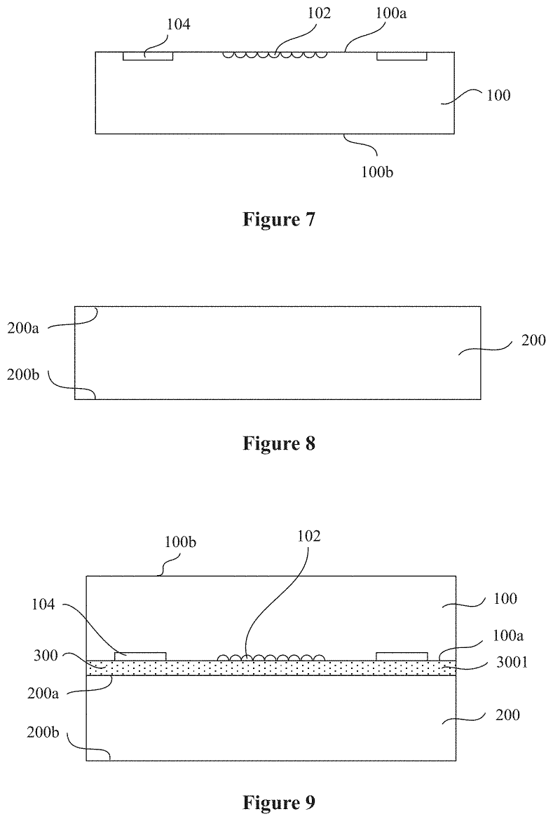

Reference is made to FIG. 6 and FIG. 7. FIG. 6 is a schematic top view of a to-be-packaged wafer according to an embodiment of the present disclosure. FIG. 7 is a schematic sectional view taken along a line AA1 in FIG. 6. A to-be-packaged wafer 10 is provided. The to-be-packaged wafer 10 includes chip units 100 and a cutting trench 101 formed between adjacent chip units 100. The to-be-packaged wafer 10 has a first surface 100a and a fourth surface 100b opposite to each other. Each of the chip units 100 includes a device region 102 located on the first surface 100a. The cutting trench 101 is used to cut the chip units 100 in a subsequent process to form separate chip packages.

In some embodiments, the chip unit 100 is an image sensing chip unit. The chip unit 100 further includes contact pads 104 located around the device region 102 on the first surface 100a. An optical signal irradiated to the device region 102 can be converted into an electrical signal with the device region 102. The device region 102 is a photosensitive region. For example, the device region 102 may be formed by multiple photodiodes arranged in an array. The device region 102 may further be provided with an association circuit connected with the image sensing chip unit, for example, a driving unit (which is not shown) for driving the chip, a reading unit (which is not shown) for acquiring a photocurrent, and a processing unit (which is not shown) for processing a current in the photosensitive region. Each of the contact pads 104 is used as an input and output terminal for connecting a device in the device region 102 with an external circuit.

In other embodiments, the device region 102 may be implemented by a physical sensor such as another type of optoelectronic device, a radio frequency device, a surface acoustic wave device, a pressure sensing device, for performing measurement based on a change in a physical quantity such as heat, light, and pressure, or a micro-electromechanical system, or a microfluidic system.

Referring to FIG. 8, a protective cover plate 200 is provided. The protective cover plate 200 has a second surface 200a and a third surface 200b opposite to each other. In some embodiments, the protective cover plate 200 is made of a light transmissive material, for example, inorganic glass or organic glass. Specifically, the protective cover plate 200 is made of optical glass.

Referring to FIG. 9, an adhesive unit 300 having a variable viscosity is formed, and the first surface 100a of the chip unit 100 is bonded with the second surface 200a of the protective cover plate 200, to press the chip unit 100 on the protective cover plate 200 by the adhesive unit. The adhesive unit is not only used for adhering, but also used for insulating and sealing.

In some embodiments, the adhesive unit 300 has a single-layer structure and is implemented by a first adhesive layer 3001. The first adhesive layer 3001 is made of an adhesive having a variable viscosity, including a photosensitive adhesive and a hot melt adhesive.

In some embodiments, forming the first adhesive layer 3001 having a variable viscosity and bonding the first surface 100a of the chip unit 100 with the second surface 200a of the protective cover plate 200 is performed by forming the first adhesive layer 3001 on the second surface 200a of the protective cover plate 200 and bonding the first surface 10a of the chip unit 100 with the first adhesive layer 3001.

In other embodiments, forming the first adhesive layer 3001 having a variable viscosity and bonding the first surface 100a of the chip unit 100 with the second surface 200a of the protective cover plate 200 is performed by forming the first adhesive layer 3001 on the first surface 100a of the chip unit 100 and bonding the second surface 200a of the protective cover plate 200 with the first adhesive layer 3001.

Next, the to-be-packaged wafer is packaged.

Specifically, the to-be-packaged wafer is thinned on the fourth surface 100b of the to-be-packaged wafer, so as to form through holes in a subsequent etching process. The to-be-packaged wafer may be thinned by a mechanical polishing process or a chemical mechanical polishing process.

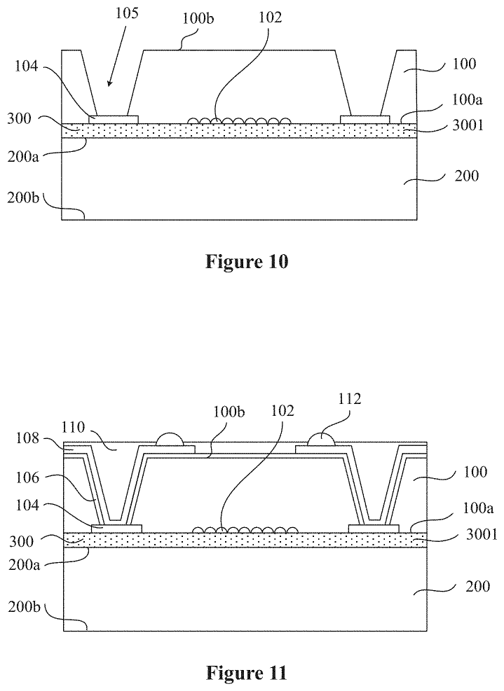

Referring to FIG. 10, the to-be-packaged wafer is etched on the fourth surface 100b of the to-be-packaged wafer to form through holes 105. Each of the through holes 105 exposes one of the contact pads 104 on the first surface 100a of the to-be-packaged wafer.

Referring to FIG. 11, an insulation layer 106 is formed on the fourth surface 100b and sidewalls of the through holes 105 (as shown in FIG. 10). The insulation layer 106 exposes the contact pad 104 located at the bottom of each of the through holes. The insulation layer 106 may provide electrical insulation for the fourth surface 100b of the to-be-packaged wafer, and may also provide electrical insulation for a substrate of to-be-packaged wafer exposed by the through holes. The insulation layer 106 may be made of silicon oxide, silicon nitride, silicon oxynitride or insulating resin.

Next, a metal layer 108 is formed on the insulation layer 106 and inner walls of the through holes 105. The metal layer 108 may be used as a wiring layer to lead the contact pads 104 to the fourth surface 100b and then connect the contact pads with an external circuit. The metal layer 108 is formed by depositing and etching a metal thin film.

Next, a solder mask 110 is formed on the metal layer 108 and the insulation layer 106 to fill the through holes 105, and openings (which are not shown) are formed on the solder mask 110 to expose a portion of the metal layer 108. The solder mask 110 is made of an insulation dielectric material such as silicon oxide and silicon nitride, to protect the metal layer 108.

Next, solder bumps 112 are formed on the solder mask 110. Each of the solder bumps 112 fills one of the openings. The solder bumps 112 may be connection structures such as solder balls and metal pillars, and may be made of a metal material such as copper, aluminum, gold, tin, and plumbum.

The to-be-packaged wafer 10 (as shown in FIG. 6) formed after the packaging process, the first adhesive layer 3001 and the protective cover plate 200 are cut along the cutting trench 101 to form multiple separate packages.

Next, the first adhesive layer 3001 in each of the multiple separate packages is processed to form a first region and a second region having different viscosities in the first adhesive layer 3001.

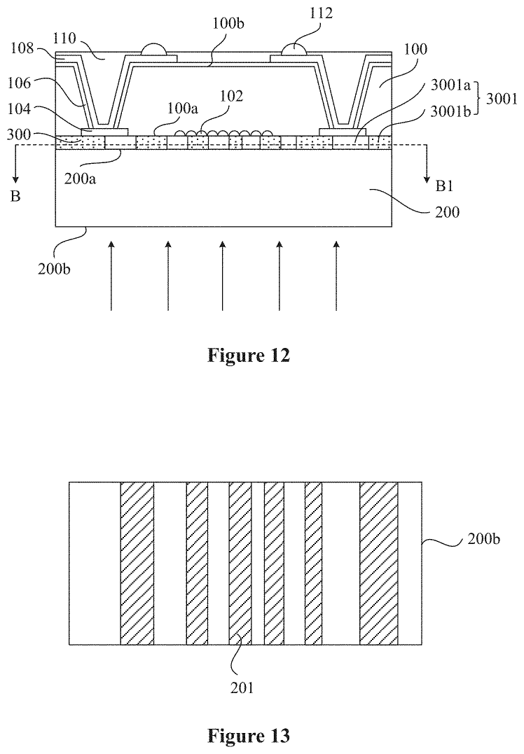

Referring to FIG. 12, in a case that the first adhesive layer 3001 is made of the photosensitive adhesive, processing the first adhesive layer 3001 to form the first region 3001a and the second region 3001b having different viscosities in the first adhesive layer 3001 is performed by irradiating a portion of the first adhesive layer 3001 with a light source having a certain wavelength. A viscosity of the portion being irradiated by the light source is decreased to form the first region 3001a, and a viscosity of a portion of the first adhesive layer 3001 not irradiated by the light source is not changed to form the second region 3001b. The wavelength of the light source is in a range in which the viscosity of the photosensitive adhesive can change.

Specifically, the first adhesive layer 3001 is made of an ultraviolet photosensitive adhesive. The viscosity of the ultraviolet photosensitive adhesive can be controlled by controlling external impacts such as a time period and power of the ultraviolet light radiation. In an embodiment, the first region 3001a is formed by irradiating a portion of the first adhesive layer 3001 with ultraviolet light, and the viscosity of the first region 3001a formed after being irradiated by the ultraviolet light is 30% of the viscosity before being irradiated by the ultraviolet light. In another embodiment, the viscosity of the first region 3001a formed after being irradiated by the ultraviolet light is 50% of the viscosity before being irradiated by the ultraviolet light. In another embodiment, the viscosity of the first region 3001 formed after being irradiated by the ultraviolet light is zero.

In an embodiment, the light source is a laser light source, and irradiating a portion of the first adhesive layer 3001 is performed by irradiating the third surface 200b of the protective cover plate 200 with the laser light source along a predetermined path. The third surface 200b is opposite to the second surface 200a. The protective cover plate 200 is made of a light transmissive material, for example, organic glass or inorganic glass.

Since the laser light has directivity, a portion of the first adhesive layer 3001 can be selectively irradiated along a predetermined path. Reference is made to FIG. 13, which is a schematic plan view of the third surface 200b of the protective cover plate 200. The portion of the third surface 200b irradiated by the laser light source is a portion indicated by 201. The predetermined path along which the laser light source irradiates is not limited in the embodiment of the present disclosure. The predetermined path may be a straight line, a curve, or a polyline. The laser irradiation portion 201 shown in FIG. 13 is merely illustrative.

In some embodiments, an area of the portion 201 of the third surface 200b irradiated by the laser light source is 30% to 90% of an area of the third surface 200b. For example, the area of the portion 201 may be 50%, 60%, 70% or 80% of the area of the third surface 200b.

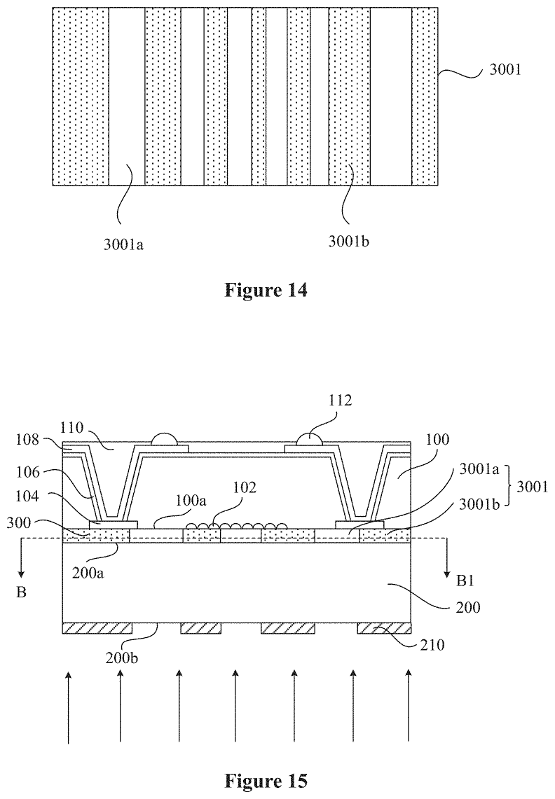

Reference is made to FIG. 14, which is a schematic sectional view taken along a line BB1 in FIG. 12. Since the protective cover plate 200 is made of a light transmissive material, the laser light source can be transmitted through the protective cover plate 200 and irradiates the surface of the first adhesive layer 3001. A viscosity of a portion of the first adhesive layer 3001 irradiated by the laser light source is decreased to form the first region 3001a, and a viscosity of a portion of the first adhesive layer 3001 not irradiated by the laser light source is not changed to form the second region 3001b. In some embodiments, the viscosity of the first region 3001a formed after being irradiated by the laser light source is zero, and the formed first region 3001a accounts for 30% to 90% by volume of the first adhesive layer 3001. For example, the first region 3001a may account for 50%, 60%, 70% or 80% by volume of the first adhesive layer 3001. In this case, the bonding force between the chip unit 100 and the protective cover plate 200 can be reduced but not completely eliminated.

In some embodiments, the light source is a surface light source, and irradiating a portion of the first adhesive layer 3001 is performed as follows.

Referring to FIG. 15, a patterned light shielding layer 210 is formed on the third surface 200b of the protective cover plate 200, with the patterned light shielding layer 210 expose a portion of the protective cover plate 200. The third surface 200b is irradiated with the surface light source. The wavelength of the surface light source is in a range in which the viscosity of the photosensitive adhesive can change. The surface light source is transmitted through the exposed portion of the protective cover plate 200 and irradiates a portion of the first adhesive layer 3001. A viscosity of the portion of the first adhesive layer 3001 irradiated by the surface light source is decreased to form the first region 3001a, and a viscosity of a portion of the first adhesive layer 3001 not irradiated by the surface light source is not changed to form the second region 3001b. In some embodiments, the viscosity of the first region 3001a formed after being irradiated by the surface light source is zero, and the formed first region 3001a accounts for 30% to 90% by volume of the first adhesive layer 3001.

The protective cover plate 200 is made of a light transmissive material, for example, organic glass or inorganic glass. In some embodiments, the light shielding layer 210 may be removed after the first region 3001a and the second region 3001b are formed. In other embodiments, the light shielding layer 210 is removed together with the protective cover plate 200 after the package is installed on the board at the client.

In some embodiments, in a case that the first adhesive layer 3001 is made of a hot melt adhesive, processing the first adhesive layer 3001 to form the first region 3001a and the second region therein 3001b having different viscosities in the first adhesive layer 3001 is performed as follows.

A portion of the first adhesive layer 3001 is positioned by using laser or ultrasound, and the portion of the first adhesive layer 3001 is heated. The viscosity of the irradiated portion of the first adhesive layer 3001 is decreased to form the first region 3001a, and the viscosity of a portion of the first adhesive layer 3001 not irradiated is not changed to form the second region 3001b.

In this way, the package shown in FIG. 1 is formed by using the packaging method according to the present embodiment.

With the packaging method according to the present embodiment, a first adhesive layer 3001 having a variable viscosity is formed to bond the to-be-packaged wafer with the protective cover plate 200, and the first adhesive layer 3001 is processed by irradiation or heating to form the first region 3001a and the second region 3001b having different viscosities in the first adhesive layer 3001. The viscosity of the first region 3001a is decreased and the viscosity of the second region 3001b is unchanged, so that the bonding force between the chip unit 100 and the protective cover plate 200 can be reduced but not completely eliminated.

In a subsequent process that the formed package is installed on a board at the client, for example, in a process that the formed package is electrically connected with a circuit board such as a Print Circuit Board, the protective cover plate 200 can still protect the package from contamination or damage. After the package is installed on the board at the client, the protective cover plate 200 can be easily removed due to the weak bonding force between the chip unit 100 and the protective cover plate 200). For example, the protective cover plate 200 may be separated from the chip unit 100 by applying an adsorption force to the back of the protective cover plate 200 by vacuum adsorption or electrostatic adsorption. The first surface 100a of the chip unit 100 separated from the protective cover plate 200 may be cleaned to remove the adhesive layer remaining on a surface of a photosensitive region.

After the package is installed on the board, the protective cover plate 200 is removed, which prevents the protective cover plate 200 from adversely affecting the image quality of the chip unit 100 during use of the chip unit 100, which is caused by the fact that the protective cover plate 200 absorbs, refracts and/or reflects light and thus affects an amount of light entering into the device region 102.

In addition, a packaging method for forming the package shown in FIG. 2 is further provided according to another embodiment of the present disclosure.

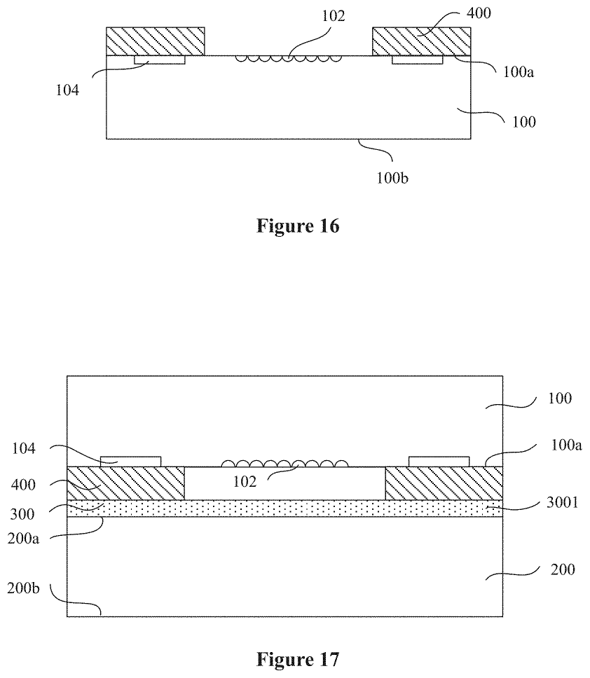

FIGS. 16 to 20 are respectively schematic sectional views of intermediate structures formed in a packaging method according to another embodiment of the present disclosure.

The present embodiment differs from the previous embodiment in that forming the adhesive unit having a variable viscosity and bonding the first surface 100a of the chip unit 100 with the second surface 200a of the protective cover plate 200 includes: forming a support structure on the first surface 100a of the chip unit 100; and bonding the support structure with the chip unit.

Referring to FIG. 16, a support structure 400 is formed on the first surface 100a of the chip unit 100, and the support structure 400 is located outside the device region 102.

In an embodiment, the support structure 400 is made of a photoresist, and the support structure 400 may be formed by applying the photoresist on the first surface 100a of the to-be-packaged wafer 10 and forming the support structure 400 exposing the device region 102 by an exposure and development process.

In other embodiments, the support structure 400 may be made of silicon oxide, silicon nitride or silicon oxynitride, and the support structure 400 may be formed by steps including: depositing a support structure material layer on the first surface 100a of the to-be-packaged wafer 10, patterning the support structure material layer to expose the device region 102, and removing a portion of the support structure material layer to form the support structure 400.

Referring to FIG. 17, an adhesive unit having a variable viscosity is formed on the second surface 200a of the protective cover plate 200. In some embodiments, the adhesive unit 300 has a single-layer structure and is implemented by a first adhesive layer 3001.

The support structure 400 is bonded with the first adhesive layer 3001. The protective cover plate 200 is pressed on the chip unit 100 by the support structure 400 and the first adhesive layer 3001, so that the device region 102 is located in a cavity surrounded by the support structure 400 and the first surface 100a, which protects the device region 102 from damage and contamination.

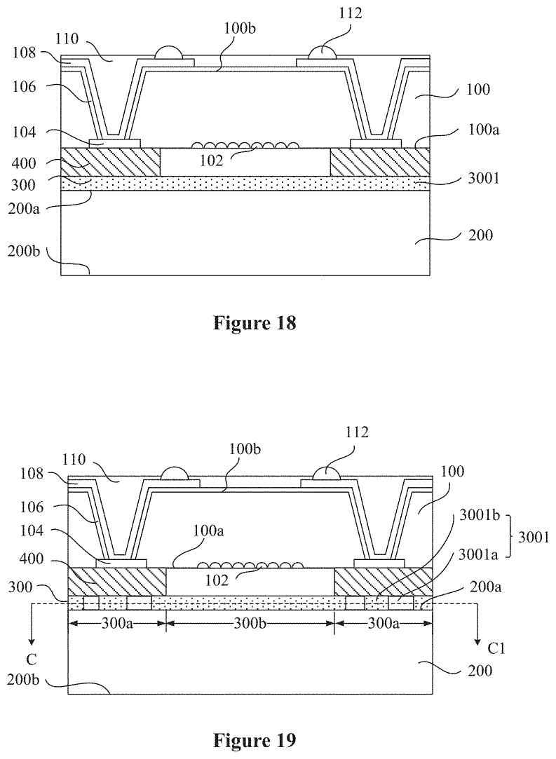

Next, the to-be-packaged wafer is packaged. The packaging method for the to-be-packaged wafer in the present embodiment is similar to that in the previous embodiment. Referring to FIG. 18, through holes (which are not shown), an insulation layer 106, a metal layer 108, a solder mask 110 and solder bumps 112 are sequentially formed in the to-be-packaged wafer. The specific details thereof are illustrated in the previous embodiment, which are not repeated herein.

The to-be-packaged wafer 10 (as shown in FIG. 6) formed after the packaging process, the support structure 400, the first adhesive layer 3001, and the protective cover plate 200 are cut along the cutting trench 101 to form multiple separate packages.

Next, the first adhesive layer 3001 in each of the multiple separate packages is processed to form the first region 3001a and the second region 3001b having different viscosities. The viscosity of the first region 3001a is less than that of the second region 3001b.

The method for forming the first region 3001a and the second region 3001b is similar to that in the previous embodiment. The viscosity of a portion of the first adhesive layer 3001 may be changed by light irradiation or heating according to the material forming the first adhesive layer 3001.

The present embodiment further differs from the previous embodiment in that the position of the first region 3001a in the formed adhesive layer 3001. In the present embodiment, since only the portion of the first adhesive layer 3001 between the support structure 400 and the second surface 200a is used for adhering, it is required to only change the viscosity of the portion of the first adhesive layer 3001 in contact with the support structure 400 to reduce the adhesive force.

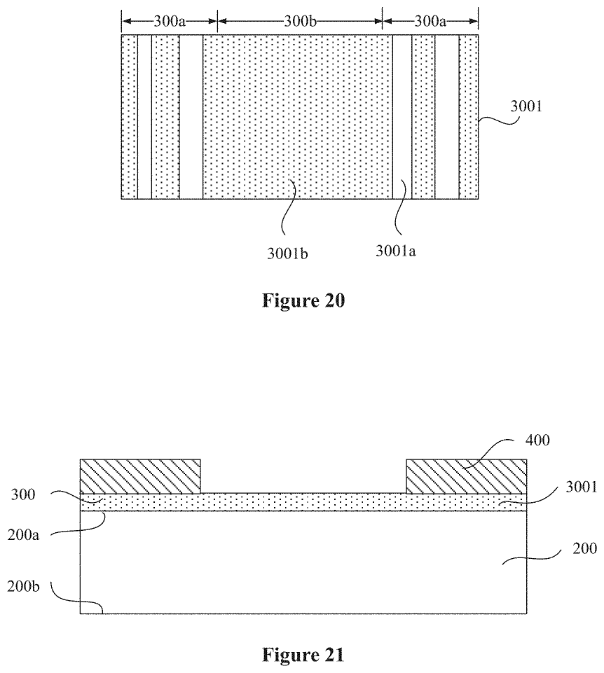

Reference is made to FIG. 19 and FIG. 20. FIG. 20 is a schematic sectional view taken along a line CC1 in FIG. 19. The first region 3001a of the formed first adhesive layer 3001 is only distributed between the support structure 400 and the second surface 200a, that is, at two end regions 300a of the first adhesive layer 3001. The second region 3001b of the first adhesive layer 3001 is all distributed at a position opposite to the device region 102, that is, at an intermediate region 300b of the first adhesive layer 3001. Therefore, in the case that the third surface 200b of the protective cover plate 200 is irradiated with the laser light source, the predetermined path is required to be changed so that the laser light source irradiates only the portion of the third surface 200b opposite to the support structure 400. In the case that the third surface 200b of the protective cover plate 200 is irradiated with the surface light source, the formed patterned light shielding layer is required to be changed to expose the portion of the third surface 200b opposite to the support structure 400. In the case that the viscosity of a portion of the first adhesive layer 3001 is changed by heating, a portion of the first adhesive layer 3001 between the support structure 400 and the second surface 200a is positioned by using laser, infrared light or ultrasound, and the portion of the first adhesive layer 3001 is heated.

In some embodiments, the viscosity of the formed first region 3001a is zero, and the first region 3001a accounts for 30% by volume of the first adhesive layer 3001, so that the bonding force between the chip unit 100 and the protective cover plate 200 can be reduced but not completely eliminated.

In this way, the package shown in FIG. 2 is formed by using the packaging method according to the present embodiment.

With the packaging method according to the present embodiment, the chip unit 100 is bonded with the protective cover plate 200 sequentially via the support structure 400, and the first region 3001a and the second region 3001b having different viscosities, where the viscosity of the first region 3001a is decreased and the viscosity of the second region 3001b is unchanged, so that the bonding force between the chip unit 100 and the protective cover plate 200 can be reduced but not completely eliminated. In addition, since the protective cover plate 200 is separated from the chip unit 100 by the support structure 400, and the device region 102 is not in contact with the first adhesive layer 3001, it is not required to clean the first surface 100a of the chip unit 100 after the protective cover plate 200 is removed.

In addition, a packaging method for forming the package shown in FIG. 3 is further provided according to another embodiment of the present disclosure.

FIGS. 21 to 24 are schematic sectional views of intermediate structures formed in a packaging method according to another embodiment of the present disclosure.

The present embodiment differs from the previous embodiment in that forming the adhesive unit having a variable viscosity and bonding the first surface 100a of the chip unit 100 with the second surface 200a of the protective cover plate 200 further includes: forming a support structure on the adhesive unit; and bonding the support structure with the first surface 100a of the chip unit 100 by an adhesive layer, which is illustrated in detail below.

Referring to FIG. 21, an adhesive unit 300 is formed on the protective cover plate 200. The adhesive unit 300 has a single-layer structure and is implemented by a first adhesive layer 3001. A support structure 400 is formed on the first adhesive layer 3001.

In some embodiments, the support structure 400 may be made of a photoresist, resin, silicon oxide, silicon nitride or silicon oxynitride.

In an embodiment, the support structure 400 is made of a photoresist, and the support structure 400 may be formed by applying the photoresist on first adhesive layer 3001 and exposing a portion of the first adhesive layer 3001 by an exposure and development process to form the support structure 400.

In other embodiments, the support structure 400 may be made of silicon oxide, silicon nitride or silicon oxynitride, and the support structure 400 may be formed by steps including: depositing a support structure material layer on the first adhesive layer 3001, patterning the support structure material layer to expose a portion of the first adhesive layer 3001, and removing a portion of the support structure material layer to form the support structure 400.

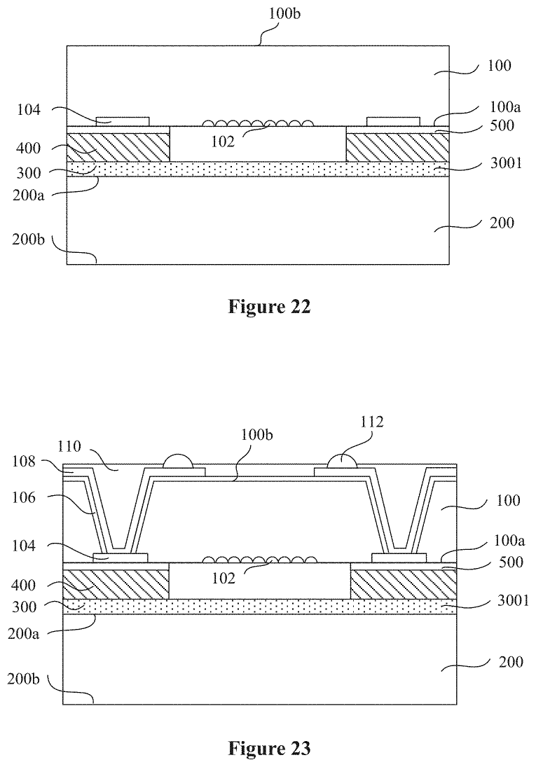

Referring to FIG. 22, the support structure 400 is bonded with the first surface 100a of the to-be-packaged wafer by the adhesive layer 500 to secure the protective cover plate 200 to the to-be-packaged wafer, and the device region 102 is located in a groove surrounded by the support structure 400 and the first adhesive layer 3001.

The adhesive layer 500 may be made of an adhesive having a constant viscosity or a variable viscosity. In some embodiments, the adhesive layer 500 is made of an adhesive having a constant viscosity, including an encapsulated adhesive such as epoxy resin.

In some other embodiments, the adhesive layer 500 may be made of an adhesive having a variable viscosity, which is different from the adhesive forming the first adhesive layer 3001 in property. For example, the first adhesive layer 3001 is made of a photosensitive adhesive, and the adhesive layer 500 is made of a hot melt adhesive. Alternatively, the first adhesive layer 3001 is made of a hot melt adhesive, and the adhesive layer 500 is made of a photosensitive adhesive. That is, in a subsequent process that the viscosity of a portion of the first adhesive layer 3001 is changed by light irradiating or heating to form the first region and the second region having different viscosities, the viscosity of the adhesive layer 500 can remain unchanged.

Next, the to-be-packaged wafer is packaged. The packaging method for the to-be-packaged wafer in the present embodiment is similar to that in the previous embodiment. Referring to FIG. 23, through holes (which are not shown), an insulation layer 106, a metal layer 108, a solder mask 110 and solder bumps 112 are sequentially formed in the to-be-packaged wafer. The specific details thereof are illustrated in the previous embodiment, which are not repeated herein.

The to-be-packaged wafer 10 (as shown in FIG. 6) formed after the packaging process, the adhesive layer 500, the support structure 400, the first adhesive layer 3001, and the protective cover plate 200 are cut along the cutting trench 101 to form multiple separate packages.

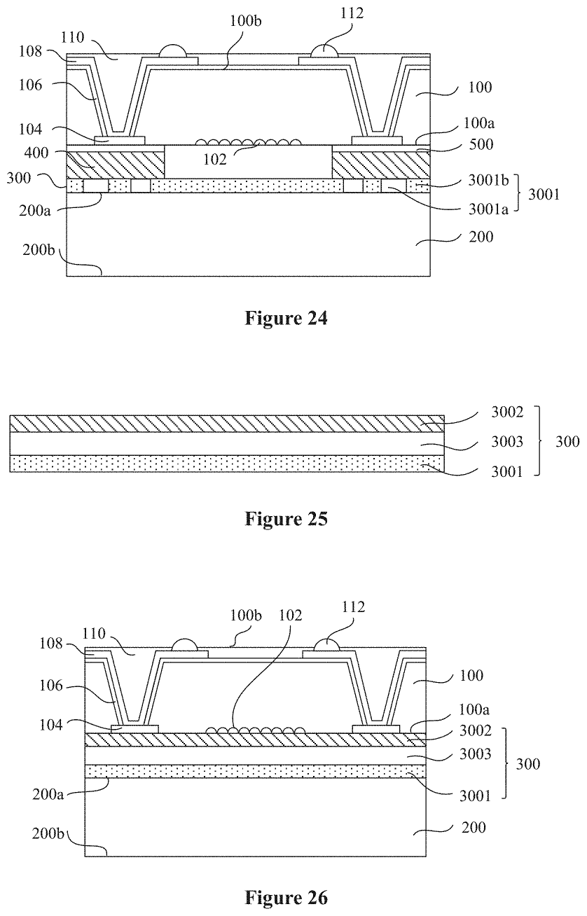

Referring to FIG. 24, the first adhesive layer 3001 in each of the multiple separate packages is processed to form the first region 3001a and the second region 3001b having different viscosities in the first adhesive layer 3001. The viscosity of the first region 3001a is less than that of the second region 3001b. The method for forming the first region 3001a and the second region 3001b is similar to that in the previous embodiment, which is not repeated herein.

In this way, the package shown in FIG. 3 is formed by using the packaging method according to the present embodiment.

With the packaging method according to the present embodiment, the chip unit 100 is bonded with the protective cover plate 200 sequentially via the adhesive layer 500, the support structure 400, and the first region 3001a and the second region 3001b having different viscosities, where the viscosity of the first region 3001a is decreased and the viscosity of the second region 3001b is unchanged, so that the bonding force between the chip unit 100 and the protective cover plate 200 can be reduced but not completely eliminated.

In addition, since the protective cover plate 200 is separated from the chip unit 100 by the adhesive layer 500 and the support structure 400, and the device region 102 is not in contact with the first adhesive layer 3001 or the adhesive layer 500, it is not required to clean the first surface 100a of the chip unit 100 after the protective cover plate 200 is removed.

A packaging method for forming the package shown in FIG. 4 is further provided according to another embodiment of the present disclosure.

FIGS. 25 to 27 are schematic sectional views of intermediate structures formed in a packaging method according to another embodiment of the present disclosure.

The present embodiment differs from the above embodiments in that the formed adhesive unit has a variable viscosity and has a multi-layer structure. The adhesive unit includes a first adhesive layer, a second adhesive layer and a transparent base located between the first adhesive layer and the second adhesive layer.

Referring to FIG. 25, an adhesive unit 300 is provided. The adhesive unit 300 includes a first adhesive layer 3001, a second adhesive layer 3002, and a transparent base 3003 located between the first adhesive layer 3001 and the second adhesive layer 3002.

In some embodiments, the first adhesive layer 3001 is made of a photosensitive adhesive having a first debonding wavelength, and the second adhesive layer 3002 is made of a photosensitive adhesive having a second debonding wavelength not equal to the first debonding wavelength.

Referring to FIG. 26, the second adhesive layer 3002 is bonded with the first surface 100a of the chip unit 100, and the first adhesive layer 3001 is bonded with the second surface 200a of the protective cover plate 200. In this way, the first adhesive layer 3001 is located between the transparent base 3003 and the second surface 200a of the protective cover plate 200, and the second adhesive layer 3002 is located between the transparent base 3003 and the first surface 100a of the chip unit 100.

Next, the to-be-packaged wafer is packaged. The packaging method for the to-be-packaged wafer in the present embodiment is similar to that in the previous embodiment, which is not repeated herein.

The to-be-packaged wafer 10 (as shown in FIG. 6) formed after the packaging process, the adhesive unit 300, and the protective cover plate 200 are cut along the cutting trench to form multiple separate packages. The adhesive unit 300 in each of the multiple separate packages is processed to form the first region and the second region having different viscosities in the adhesive unit 300.

In this embodiment, the first region and the second region may be formed by processing the first adhesive layer 3001 of the chip unit 300 to form the first region and the second region in the first adhesive layer 3001.

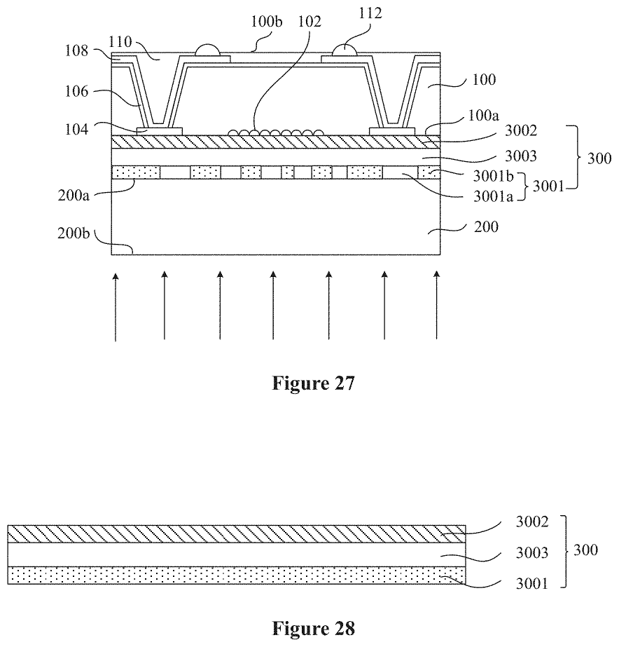

Referring to FIG. 27, a portion of the first adhesive layer 3001 is irradiated with a light source having the first debonding wavelength. A viscosity of the portion of the first adhesive layer irradiated by the light source is decreased to form a first region 3001a, and a viscosity of a portion of the first adhesive layer not irradiated by the light source is not changed to form a second region 3001b. The method for forming the first region 3001a and the second region 3001b in the first adhesive layer 3001 is similar to that in the above embodiments, which is not repeated herein.

It should be noted that, since the first debonding wavelength is not equal to the second debonding wavelength, the viscosity of the second adhesive layer 3002 is unchanged in a process that the first adhesive layer 3001 is irradiated with the light source having the first debonding wavelength.

In this way, the package shown in FIG. 4 is formed by using the packaging method according to the present embodiment.

It should be noted that the second adhesive layer 3002 may be irradiated with a light source having the second debonding wavelength in a subsequent process to decrease the viscosity of the second adhesive layer 3002 or even to zero, so as to separate the chip unit 100 from the transparent base 3003.

With the packaging method according to this embodiment, the bonding force between the chip unit 100 and the protective cover plate 200 can still be reduced but not completely eliminated. In a subsequent process that the package is installed on a board at the client, the transparent base 3003 can protect the package from contamination or damage. After the package is installed on the board at the client, the protective cover plate 200 can be easily removed, and then a portion of the second adhesive layer 3002 is irradiated by a light source having the second debonding wavelength to decrease the viscosity of the second adhesive layer 3002, so as to separate the transparent base 3003 from the chip unit 100, which prevents the transparent base 3003 from adversely affecting the image quality of the chip unit 100 during use of the chip unit 100.

A packaging method for forming the package shown in FIG. 5 is further provided according to another embodiment of the present disclosure.

FIGS. 28 to 30 are schematic sectional views of intermediate structures formed in a packaging method according to another embodiment of the present disclosure.

The present embodiment is similar to the previous embodiment. The formed adhesive unit has a variable viscosity and has a multi-layer structure. The adhesive unit includes a first adhesive layer, a second adhesive layer and a transparent base located between the first adhesive layer and the second adhesive layer.

Referring to FIG. 28, an adhesive unit 300 is provided. The adhesive unit 300 includes a first adhesive layer 3001, a second adhesive layer 3002, and a transparent base 3003 located between the first adhesive layer 3001 and the second adhesive layer 3002. The first adhesive layer 3001 is made of a photosensitive adhesive having a first debonding wavelength, and the second adhesive layer 3002 is made of a photosensitive adhesive having a second debonding wavelength not equal to the first debonding wavelength.

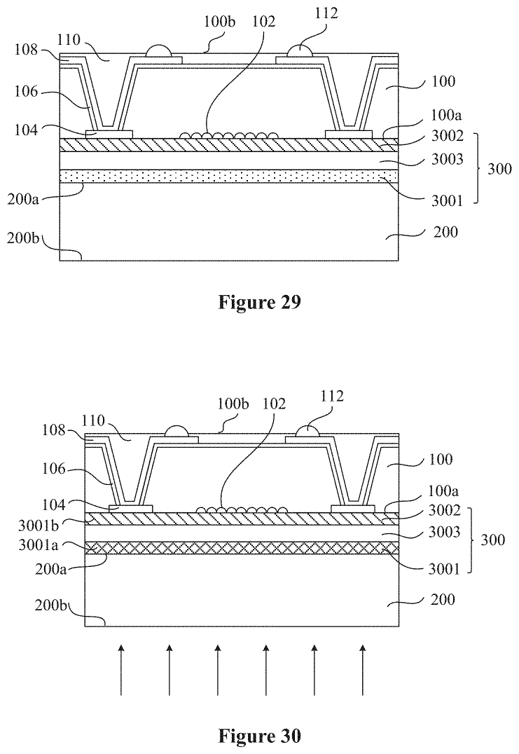

Referring to FIG. 29, the first adhesive layer 3001 is bonded with the second surface 200a of the protective cover plate 200, and the second adhesive layer 3002 is bonded with the first surface 100a of the chip unit 100. In this way, the first adhesive layer 3001 is located between the transparent base 3003 and the second surface 200a of the protective cover plate 200, and the second adhesive layer 3002 is located between the transparent base 3003 and the first surface 100a of the chip unit 100.

The present embodiment differs from the previous embodiment in that the method for processing the adhesive unit 300 to form the first region and the second region having different viscosities in the adhesive unit 300.

Referring to FIG. 30, the adhesive unit 300 is irradiated with a light source having the second debonding wavelength. Since the first debonding wavelength is not equal to the second debonding wavelength, the viscosity of the first adhesive layer 3001 is decreased to form a first region 3001a, and the viscosity of the second adhesive layer 3002 is unchanged to form a second region 3001b. The viscosity of the first region 3001a is less than that of the second region 3001b.

In some embodiments, the protective cover plate 200 is made of a light transmissive material including inorganic glass and organic glass. A light source having the first debonding wavelength may vertically irradiate the third surface 200b of the protective cover plate 200, to irradiate the first adhesive layer 3001, so that the viscosity of the first adhesive layer 3001 is decreased to form the first region 3001a.

It can be seen that the present embodiment differs from the previous embodiment in that the viscosity of the entire first adhesive layer 3001 is reduced, which is not the same as that described in the previous embodiment that the viscosity of only a portion of the first adhesive layer 3001 is changed.

In this way, the package shown in FIG. 5 is formed by using the packaging method according to the present embodiment.

It should be noted that the second adhesive layer 3002 may be irradiated with a light source having the second debonding wavelength in a subsequent process to decrease the viscosity of the second adhesive layer 3002 or even to zero, so as to separate the chip unit 100 from the transparent base 3003.

With the packaging method according to the present embodiment, the viscosity of the first adhesive layer 3001 is decreased, so that the protective cover plate 200 can be easily separated from the transparent base 3003 before shipment of the package, and the package including the chip unit 100, the transparent base 3003 and the second adhesive layer 3002 is provided to the client. In a subsequent process that the package is installed on a board at the client, the transparent base 3003 can still protect the package from contamination or damage. After the package is installed on the board at the client, the second adhesive layer 3002 is irradiated by a light source having the second debonding wavelength to decrease the viscosity of the second adhesive layer 3002, so as to separate the transparent base 3003 from the chip unit 100, which prevents the transparent base 3003 from adversely affecting the image quality of the chip unit 100 during use of the chip unit 100.

In summary, with the package and the packaging method according to the embodiments of the present disclosure, the bonding force between the chip unit and the protective cover plate can be reduced but not completely eliminated. In a subsequent process that the package is installed on a board at the client, the protective cover plate can still protect the package from contamination or damage. After the package is installed on the board at the client, the protective cover can be easily removed, which prevents the protective cover plate from adversely affecting performance of the chip unit during use of the chip unit.

Further, the packaging method further includes forming an adhesive unit having a variable viscosity, where the adhesive unit includes a first adhesive layer, a second adhesive layer and a transparent base located between the first adhesive layer and the second adhesive layer. The first adhesive layer is located between the transparent base and the second surface of the protective cover plate, and the second adhesive layer is located between the transparent base and the first surface of the chip unit. The first adhesive layer serves as the first region, and the second adhesive layer serves as the second region. The protective cover plate may be removed before shipment of the package. In a subsequent process that the package is installed on a board at the client, the transparent base can still protect the package from contamination or damage. After the package is installed on the board at the client, the second adhesive layer is irradiated by a light source having the second debonding wavelength to decrease the viscosity of the second adhesive layer, so as to separate the transparent base from the chip unit, which prevents the transparent base from adversely affecting the image quality of the chip unit during use of the chip unit.

The present disclosure is disclosed above, which is not limited thereto. Those skilled in the art may make various changes and modifications to the technical solutions of the present disclosure without departing from the spirit and scope of the present disclosure. Therefore, the protection scope of the present disclosure is defined by the appended claims.

1. A package, comprising:
a chip unit having a first surface, wherein the first surface comprises a device region;
a protective cover plate having a second surface opposite to the first surface of the chip unit; and
an adhesive unit located between the first surface of the chip unit and the second surface of the protective cover plate and configured to bond the chip unit with the protective cover plate, wherein the adhesive unit comprises a first region and a second region having different viscosities.

2. The package according to claim 1, wherein the viscosity of the first region is less than the viscosity of the second region.

3-4. (canceled)

5. The package according to claim 1, wherein the adhesive unit comprises a first adhesive layer, with the first region and the second region being in the first adhesive layer.

6. The package according to claim 2, wherein the adhesive unit comprises:
a first adhesive layer;
a second adhesive layer; and
a transparent base located between the first adhesive layer and the second adhesive layer, wherein
the first adhesive layer is located between the transparent base and the second surface of the protective cover plate, and the second adhesive layer is located between the transparent base and the first surface of the chip unit.

7. The package according to claim 6, wherein the first region and the second region are located in the first adhesive layer.

8. The package according to claim 6, wherein the first region of the adhesive unit is the first adhesive layer, and the second region of the adhesive unit is the second adhesive layer.

9. The package according to claim 1, further comprising: a support structure, wherein
the support structure is located between the first surface of the chip unit and the adhesive unit, with the device region being located in a groove surrounded by the support structure and the adhesive unit; or
the support structure is located between the first surface of the chip unit and the adhesive unit, and the support structure is bonded with the first surface of the chip unit by an adhesive layer, with the device region being located in a groove surrounded by the support structure and the adhesive unit.

10. (canceled)

11. A packaging method, comprising:
providing a chip unit having a first surface, wherein the first surface comprises a device region;
providing a protective cover plate having a second surface; and
forming an adhesive unit for bonding the first surface of the chip unit with the second surface of the protective cover plate, wherein
the adhesive unit comprises a first region and a second region having different viscosities.

12. The packaging method according to claim 11, wherein the forming an adhesive unit for bonding the first surface of the chip unit with the second surface of the protective cover plate comprises:
forming an adhesive unit having a variable viscosity and bonding the first surface of the chip unit with the second surface of the protective cover plate; and
processing the adhesive unit to form the first region and the second region having different viscosities in the adhesive unit.

13. The packaging method according to claim 12, wherein the viscosity of the first region is less than the viscosity of the second region.

14-15. (canceled)

16. The packaging method according to claim 13, wherein the adhesive unit comprises a first adhesive layer.

17. The packaging method according to claim 13, wherein the adhesive unit comprises:
a first adhesive layer;
a second adhesive layer; and
a transparent base located between the first adhesive layer and the second adhesive layer, wherein
the first adhesive layer is located between the transparent base and the second surface of the protective cover plate, and the second adhesive layer is located between the transparent base and the first surface of the chip unit.

18. The packaging method according to claim 16, wherein the processing the adhesive unit to form the first region and the second region having different viscosities in the adhesive unit comprises:
processing the first adhesive layer to form the first region and the second region in the first adhesive layer.

19. The packaging method according to claim 17, wherein the processing the adhesive unit to form the first region and the second region having different viscosities in the adhesive unit comprises:
processing the first adhesive layer to decrease a viscosity of the first adhesive layer, wherein the first adhesive layer serves as the first region of the adhesive unit, and the second adhesive layer serves as the second region of the adhesive unit.

20. The packaging method according to claim 18, wherein the first adhesive layer is made of a photosensitive adhesive having a first debonding wavelength, and processing the first adhesive layer to form the first region and the second region having different viscosities in the first adhesive layer comprises:
irradiating a portion of the first adhesive layer with a light source having the first debonding wavelength, wherein a viscosity of the portion of the first adhesive layer irradiated by the light source is decreased to form the first region, and a viscosity of a portion of the first adhesive layer not irradiated by the light source is not changed to form the second region.

21. The packaging method according to claim 19, wherein the first adhesive layer is made of a photosensitive adhesive having a first debonding wavelength, the second adhesive layer is made of a photosensitive adhesive having a second debonding wavelength not equal to the first debonding wavelength, and the processing the adhesive unit to form the first region and the second region having different viscosities in the adhesive unit comprises:
irradiating the adhesive unit with a light source having the first debonding wavelength, wherein the viscosity of the first adhesive layer is decreased to be zero to form the first region, and a viscosity of the second adhesive layer is not changed to form the second region.

22. The packaging method according to claim 20, wherein the light source is a laser light source or a surface light source,
in a case that the light source is the laser light source, the irradiating a portion of the first adhesive layer comprises:
irradiating a portion of a third surface of the protective cover plate with the laser light source along a predetermined path, wherein the third surface is opposite to the second surface; and
in a case that the light source is the surface light source, the irradiating a portion of the first adhesive layer comprises:
forming a patterned light shielding layer on a third surface of the protective cover plate, with the patterned light shielding layer exposing a portion of the protective cover plate, wherein the third surface is opposite to the second surface; and
irradiating the third surface with the surface light source.

23-24. (canceled)

25. The packaging method according to claim 18, wherein the first adhesive layer is made of a hot melt adhesive, and processing the first adhesive layer to form the first region and the second region having different viscosities in the first adhesive layer comprises:
irradiating a portion of the first adhesive layer by using laser or ultrasound, wherein a viscosity of the region irradiated is decreased to form the first region, and a viscosity of a portion of the first adhesive layer not irradiated is not changed to form the second region.

26. The packaging method according to claim 12, wherein the forming an adhesive unit having a variable viscosity and bonding the first surface of the chip unit with the second surface of the protective cover plate comprises:
forming an adhesive unit on the second surface of the protective cover plate and bonding the first surface of the chip unit with the adhesive unit; or
forming an adhesive unit on the first surface of the chip unit and bonding the second surface of the protective cover plate with the adhesive unit.

27. The packaging method according to claim 12, wherein the forming an adhesive unit having a variable viscosity and bonding the first surface of the chip unit with the second surface of the protective cover plate comprises:
forming a support structure on the first surface of the chip unit, with the support structure being located outside the device region;
forming an adhesive unit having a variable viscosity on the second surface of the protective cover plate; and
bonding the support structure with the adhesive unit.

28. The packaging method according to claim 12, wherein the forming an adhesive unit having a variable viscosity and bonding the first surface of the chip unit with the second surface of the protective cover plate comprises:
forming an adhesive unit on the protective cover plate;
forming a support structure on the adhesive unit; and
bonding the support structure with the first surface of the chip unit by an adhesive layer, with the device region being located in a groove surrounded by the support structure and a surface of the adhesive unit.

29. The packaging method according to claim 12, wherein the chip unit is on a to-be-packaged wafer comprising a plurality of chip units and a cutting trench formed between adjacent chip units among the plurality of chip units;
the chip unit further comprises contact pads located on the first surface and outside the device region; and
after bonding the first surface of the chip unit with the adhesive unit and before processing the adhesive unit, the package method further comprises:
thinning the to-be-packaged wafer on a fourth surface of the to-be-packaged wafer, wherein the fourth surface of the to-be-packaged wafer is opposite to the first surface;
etching the to-be-packaged wafer on the fourth surface of the to-be-packaged wafer to form through holes, wherein each of the through holes exposes one of the contact pads;
forming an insulation layer on the fourth surface of the to-be-packaged wafer and sidewalls of the through holes;
forming a metal layer connected with the contact pads on the insulation layer;
forming a solder mask on the metal layer and the insulation layer, wherein the solder mask is provided with openings to expose a portion of the metal layer;
forming solder bumps on the solder mask, wherein each of the solder bumps fills one of the openings; and
cutting the to-be-packaged wafer, the adhesive unit and the protective cover plate along the cutting trench to form a plurality of separate packages.
